(19) United States
(12) Patent Application Publication
(10) Pub. No.: US 2013/0193542 A1
(43) Pub. Date: Aug. 1, 2013

(54) IMAGE SENSOR, PRODUCTION APPARATUS, PRODUCTION METHOD, AND IMAGING APPARATUS

(71) Applicant: Sony Corporation, Tokyo (JP)

(72) Inventor: Syogo Kurogi, Kumamoto (JP)

(73) Assignee: SONY CORPORATION, Tokyo (JP)

(21) Appl. No.: 13/743,145

(22) Filed: Jan. 16, 2013

(30) Foreign Application Priority Data
Jan. 27, 2012 (JP) 2012-014858

(51) Int. Cl. H01L 31/0232; H01L 31/18

(52) U.S. Cl. CPC H01L 31/02327; H01L 31/18
USPC 257/432; 438/57; 257/463

(57) ABSTRACT

An image sensor includes a substrate formed of a material having a light absorption coefficient higher than that of silicon, and a photoelectric conversion element formed on the substrate for photoelectrically converting incident light.

### BACKGROUND

The present disclosure relates to an image sensor, a production apparatus, a production method and an imaging apparatus. More particularly, the present disclosure relates to an image sensor, a production apparatus, a production method and an imaging apparatus capable of inhibiting occurrences of color mixing and black shift.

Visual light image sensors photoelectrically convert light having a visual light wavelength and change it to an electric signal, thereby reproducing information as if human eyes see. A silicon (Si) semiconductor has a band gap capable of photoelectrically converting light having a wavelength of up to about 1100 nm. In the visual light image sensor using the silicon (Si) substrate, an IR (infrared) cut filter for blocking infrared light is therefore attached to limit incident light arriving at the sensor to infrared light.

In recent years, by removing the IR cut filter and combining with an infrared light source, the silicon (Si) substrate image sensor is used for a night vision camera application. Some distance is necessary for long wavelength light located at near-infrared region to be photoelectrically converted in the silicon (Si) substrate. Hence the long wavelength light may arrive at a rear surface of the sensor device before being photoelectrically converted. A part of the near-infrared light reflected at the rear surface may be re-incident on a photodiode.

As described above, the near-infrared light reflected at the rear surface of the sensor device or the like may be re-incident on a photodiode of an adjacent pixel, which may induce the color mixing. Also, the near-infrared light reflected at the rear surface of the sensor device or the like may be incident on a photodiode in a pixel at an OB (Optical Black) region. So, a pixel value (OB level) at the OB region may become peculiar (increase), and a black level may not be corrected adequately (black shift may be produced) in a clamp processing.

Japanese Patent Application Laid-open No. 2005-209695 suggests a method of catching floating atoms in a p well of a pixel by forming an n type region in the p well.

Japanese Unexamined Patent Application Publication No. 2009-505437 suggests a method of preventing photoelectrons which drift in a silicon bulk from entering the OB region by covering the OB region with an n type semiconductor.

### SUMMARY

The methods described in Japanese Patent Application Laid-open No. 2005-209695 and Japanese Unexamined Patent Application Publication No. 2009-505437 are not capable of fully preventing the infrared light having a long wavelength from being re-incident, and may produce the occurrences of the color mixing and the black shift. Also, in the methods described in Japanese Patent Application Laid-open No. 2005-209695 and Japanese Unexamined Patent Application Publication No. 2009-505437, the n type region is necessary, which may increase the number of production steps and the costs.

In view of the circumstances as described above, it is desirable to inhibit the occurrences of the color mixing and the black shift due to the near-infrared light reflected at the rear surface of the sensor device or the like being incident on the photodiode.

According to an embodiment of the present disclosure, there is provided an image sensor, including a substrate formed of a material having a light absorption coefficient higher than that of silicon, and a photoelectric conversion element formed on the substrate for photoelectrically converting incident light.

The substrate may be formed of a material having a high light absorption coefficient of light having a wavelength longer than light in a visual light region.

The substrate may be formed of a material having a high light absorption coefficient of near-infrared light.

The substrate may be formed of silicon-germanium.

The image sensor may further include a silicon epitaxial layer provided by epitaxially grown silicon on the substrate, and the photoelectric conversion element may be formed on the silicon epitaxial layer.

The substrate may be formed of silicon-germanium having an uneven germanium concentration.

The germanium concentration of the substrate may be made lower towards a position shallower as seen from a light incident side.

The image sensor may further include an insulation film formed on the photoelectric conversion element.

The image sensor may further include a light shielding film for shielding external light formed on the photoelectric conversion element in a pixel at an OB (Optical Black) region.

The image sensor may further include an interconnection layer formed on the insulation film.

The image sensor may further include a color filter formed on the interconnection layer on a pixel to pixel basis, and a collecting lens formed on the color filter on a pixel to pixel basis.

According to an embodiment of the present disclosure, there is provided a production apparatus of producing an image sensor, including a substrate production part for producing a substrate formed of a material having a light absorption coefficient higher than that of silicon, and a photoelectric conversion element production part for forming a photoelectric conversion element, which photoelectrically converts incident light, on the substrate produced at the substrate production part.

The production apparatus may further include a silicon epitaxial layer production part for epitaxially growing silicon on the substrate produced at the substrate production part to form a silicon epitaxial layer thereon.

According to an embodiment of the present disclosure, there is provided a method of producing a production apparatus of producing an image sensor, including producing a substrate formed of a material having a light absorption coefficient higher than that of silicon at a substrate production part, and forming a photoelectric conversion element, which photoelectrically converts incident light, on the substrate produced at the substrate production part at a photoelectric conversion element production part.

According to an embodiment of the present disclosure, there is provided an imaging apparatus, including an image sensor for imaging an object and outputting an image of the object as an electric signal, and an image processor for image-processing the object obtained by the image sensor, in which the image sensor includes a substrate formed of a material having a light absorption coefficient higher than that of silicon, and a photoelectric conversion element formed on the substrate for photoelectrically converting incident light.

The substrate may be formed of a material having a high light absorption coefficient of a light having a wavelength longer than light in a visual light region.

The substrate may be formed of silicon-germanium.

The image sensor in the imaging apparatus may further include a silicon epitaxial layer provided by epitaxially grown silicon on the substrate, and the photoelectric conversion element may be formed on the silicon epitaxial layer.

The substrate may be formed of silicon-germanium having an uneven germanium concentration.

The germanium concentration of the substrate may be made lower towards a position shallower as seen from a light incident side.

An embodiment of the present disclosure includes a substrate formed of a material having a light absorption coefficient higher than that of silicon, and a photoelectric conversion element formed on the substrate for photoelectrically converting incident light.

According to an embodiment of the present disclosure, a substrate formed of a material having a light absorption coefficient higher than that of silicon is produced, and a photoelectric conversion element, which photoelectrically converts incident light, is formed on the substrate produced.

An embodiment of the present disclosure includes an image sensor for imaging an object and outputting an image of the object as an electric signal, and an image processor for image-processing the object obtained by the image sensor, in which the image sensor includes a substrate formed of a material having a light absorption coefficient higher than that of silicon, and a photoelectric conversion element formed on the substrate for photoelectrically converting incident light.

According to the embodiments of the present disclosure, occurrences of color mixing and black shift can be inhibited.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a cross-sectional view illustrating an occurrence of color mixing in a CMOS image sensor in the related art;

FIG. 2 is a cross-sectional view showing a configuration example of an image sensor according to an embodiment of the present disclosure;

FIGS. 3A, 3B and 3C are graphs each showing an example of light intensity in a bulk;

FIG. 4 is a graph showing an example of light intensity in a bulk at a wavelength of 1100 nm;

FIG. 5 is a graph provided by enlarging the graph shown in FIG. 4 at a distance in a bulk of from 590 to 600 μm;

FIG. 6 is a block diagram showing a major configuration example of a production apparatus for producing an image sensor;

FIG. 7 is a flow chart illustrating an example of a flow of a production process; and

FIG. 8 is a block diagram showing a major configuration example of an imaging apparatus according to an embodiment of the present disclosure.

### DETAILED DESCRIPTION OF EMBODIMENTS

Hereinafter, an embodiment of the present disclosure will be described with reference to the drawings.

The embodiments of the present disclosure will be described in the following order.
<1. First Embodiment (Image Sensor)>
<2. Second Embodiment (Production Apparatus and Production Method)>
<3. Third Embodiment (Imaging Apparatus)>

### 1. First Embodiment (Image Sensor)

### [Occurrence of Black Shift]

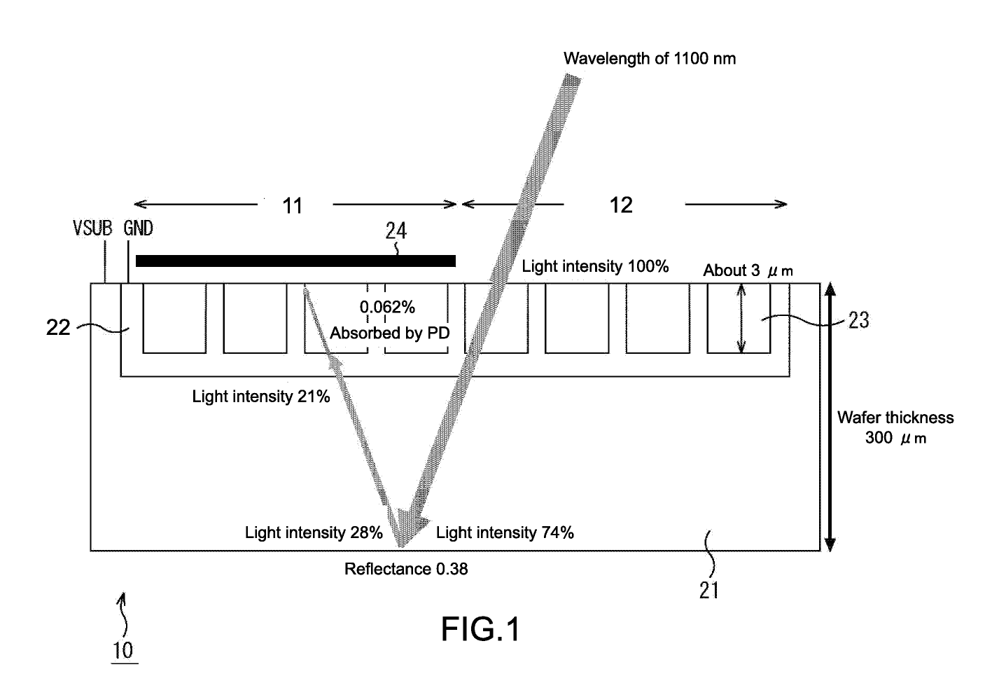

First of all, an occurrence of a black shift due to near-infrared light will be described. FIG. 1 is a cross-sectional view illustrating an occurrence of color mixing in a CMOS image sensor in the related art.

As shown in FIG. 1, the CMOS image sensor 10 in the related art includes an Nsub substrate 21, P wells 22 formed in the Nsub substrate 21, and PDs (Photodiodes) 23 formed in the P wells. The PDs 23 photoelectrically convert light incident from an upper side as shown in FIG. 1.

Specifically, each PD 23 corresponds to each pixel. Four PDs 23 positioned at left side correspond to the pixels at an OB (Optical Black) region for detecting a reference value of the black level. These pixels are covered by a light blocking film 24 at a light incident side such that no light is incident externally on the PDs 23.

Four PDs 23 positioned at right side correspond to the pixels at an effective pixel region (herein referred to as “aperture pixels 12”). In FIG. 1, eight PDs 23 are schematically shown. However, any number of PDs 23 may be used.

When infrared light having a long wavelength is incident on the CMOS image sensor 10, the light is photoelectrically converted in the PDs 23. As the infrared light has a long wavelength, a long distance is necessary for photoelectrical conversion. A part of the infrared light incident on the PDs 23 may not be photoelectrically converted and pass through the PDs 23. The infrared light passed through the PDs 23 may move through the Nsub substrate 21, be partly reflected at a rear surface of the Nsub substrate 21 and the like, be re-incident on the PDs 23, and be electrically converted.

For example, the CMOS image sensor 10 has a wafer thickness of 300 μm. A part of the light having a wavelength of 1100 nm incident on the CMOS image sensor 10 is photoelectrically converted in the PDs 23 each having a depth of about 3 μm, and the rest of the light passes through the PDs 23.

If the light having a wavelength of 1100 nm passed through the PDs 23 and arrived at the rear surface of the Nsub substrate 21 accounts for about 74% of the light incident on the CMOS image sensor, and if the reflectance of the light at the rear surface of the Nsub substrate 21 is 0.38, 28% of the light having a wavelength of 1100 nm is reflected based on the total light incident on the CMOS image sensor 10. When about 21% of the light having a wavelength of 1100 nm is re-incident on the PDs 23, about 0.062% of the light having a wavelength of 1100 nm is photoelectrically converted based on the total light incident on the CMOS image sensor 10 during the light having a wavelength of 1100 nm passes through the PDs 23.

As described above, when the infrared light reflected at the rear surface of the Nsub substrate 21 and the like is incident on the PDs 23 in the aperture pixel 12 other than the PDs 23 on which the infrared light is incident before reflecting, the color mixing may be produced. When the infrared light reflected at the rear surface of the Nsub substrate 21 and the like is incident on the PDs 23 of the pixels at the OB region 11, the reference value of the black level may become peculiar to produce the black shift.

### [Image Sensor]

According to the embodiment of the present disclosure, the image sensor uses the substrate formed of a material having a light absorption coefficient higher than that of silicon in place of the silicon (Si) substrate. For example, a silicon-germanium (SiGe) mixed crystal substrate is used.

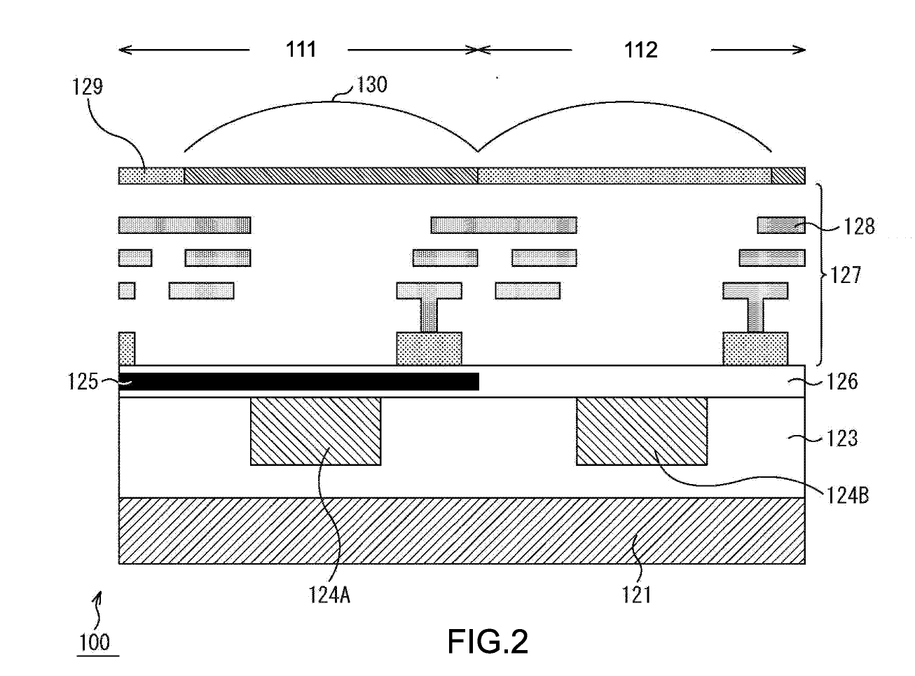

FIG. 2 is a view showing a configuration example of an image sensor according to an embodiment of the present disclosure. A CMOS (Complementary Metal Oxide Semiconductor) image sensor 100 shown in FIG. 2 is an image sensor for photoelectrically converting the incident light to output an image of an object as an electric signal.

As shown in FIG. 2, the CMOS image sensor 100 according to an embodiment of the present disclosure uses a silicon-germanium (SiGe) mixed crystal substrate 121 in place of an ordinary silicon (Si) substrate. Basically, a silicon epitaxial layer 123 is laminated on the silicon-germanium (SiGe) mixed crystal substrate 121 by epitaxially growing silicon (Si) single crystal thereon. In the silicon epitaxial layer 123, a photodiode 124A and a photodiode 124B are formed. Above the silicon epitaxial layer 123, an insulation film 126 in which a light shielding film 125 is formed, an interconnection layer 127 in which interconnections 128 are formed, a color filter 129 and a collecting lens 130 are laminated.

In FIG. 2, a configuration of a part of pixels in the CMOS image sensor 100 is shown. In FIG. 2, at a left side, a configuration example of a pixel at the OB region (OB 111) is shown, at a right side, a configuration example of a pixel at the effective pixel region (aperture pixel 112) is shown. The photodiode 124A shows an example of a photoelectric conversion element at the OB 111, and the photodiode 124B shows an example of a photoelectric conversion element in the aperture pixel 112. Although one OB 111 and one aperture pixel 112 are shown in FIG. 2, any number of pixels at the OB region and the effective pixel region may be actually used. In addition, although FIG. 2 shows the photodiode 124A and the photodiode 124B disposed adjacent, any positional relationship therebetween may be used. When the photodiode 124A and the photodiode 124B are not distinguished each other, they are simply referred to as photodiodes 124.

The photodiode 124 is an example of a photoelectric conversion element for photoelectrically converting incident light. According to the embodiment of the present disclosure, any photoelectric conversion element may be formed in the silicon epitaxial layer 123 on a pixel to pixel basis, and may be other than the photodiode. For convenience of explanation, the photodiode 124 will be explained below as the photoelectric conversion element.

As shown in FIG. 2, the OB 111 is different from the configuration of the aperture pixel 112 in that the light shielding film 125 is formed in the insulation film 126. The photodiode 124A in the OB 111 is designed such that the light shielding film 125 prevents the light from being incident externally. However, the light passed through, for example, the photodiode 124B and the like and reflected at the rear surface of the silicon substrate and the like may be actually re-incident on the photodiode 124A from the rear surface (the lower side in FIG. 2), as described above.

Therefore, the silicon-germanium (SiGe) mixed crystal substrate 121 formed of the material having a light absorption coefficient higher than that of silicon is used in place of the silicon (Si) substrate.

A band gap of germanium (Ge) is 0.66 eV, which is smaller than that of silicon (Si) being 1.11 eV. Germanium (Ge) is compatible with silicon (Si) forming a 100% solid solution. Its composition ratio can be changed continuously and freely. So, the band gap of the silicon-germanium (SiGe) can be set arbitrarily by changing an addition ratio of germanium (Ge).

For example, when the composition ratio of germanium (Ge) is increased, the band gap of the silicon-germanium (SiGe) can be decreased. Thus, the light absorption coefficient can be made higher in all wavelength regions.

Thus, the silicon-germanium (SiGe) having the light absorption coefficient higher than that of silicon single crystal in all wavelength regions can be provided. There can be provided the substrate at least having a high light absorption coefficient of light having a wavelength longer than light in a visual light region (e.g., near infrared light).

A germanium (Ge) concentration in the silicon-germanium (SiGe) mixed crystal substrate 121 is arbitrarily and may be, for example, about 10% to 20%.

As the silicon-germanium (SiGe) mixed crystal substrate 121 has light absorption coefficient higher than that of silicon single crystal substrate, the silicon-germanium (SiGe) mixed crystal substrate 121 absorb much of the incident light not photoelectrically converted but transmitted through the photodiode 124. In other words, the percentage of the light absorbed by the substrate is increased when silicon-germanium (SiGe) is used as compared with when silicon (Si) single crystal is used.

Accordingly, the CMOS image sensor 100 can inhibit the occurrence of the color mixing due to the fact that the long wavelength light drifted in the substrate is incident on the photodiode 124B at the effective pixel region (aperture pixel 112) (which is the different photodiode 124 in the different pixel when the light is incident).

Also, the CMOS image sensor 100 can inhibit the occurrence of the black shift (the peculiar reference value of the black level) due to the fact that the long wavelength light drifted in the substrate is incident on the photodiode 124A in the pixel (OB 111) at the optical black region.

By epitaxially growing the silicon (Si) single crystal on the silicon-germanium (SiGe) mixed crystal substrate 121, circuit characteristics and pixel characteristics can be designed as is the case in the use of the silicon (Si) single crystal substrate in the related art.

### [Light Absorption in Substrate]

Then, a difference in the light absorption in the substrate depending on the difference in the germanium (Ge) concentration will be described. In the below, each incident light intensity in each substrate, i.e., the silicon (Si) single crystal substrate, the silicon-germanium (SiGe) mixed crystal substrate 121 containing 10% of germanium (Ge) and the silicon-germanium (SiGe) mixed crystal substrate 121 containing 20% of germanium (Ge) is compared each other.

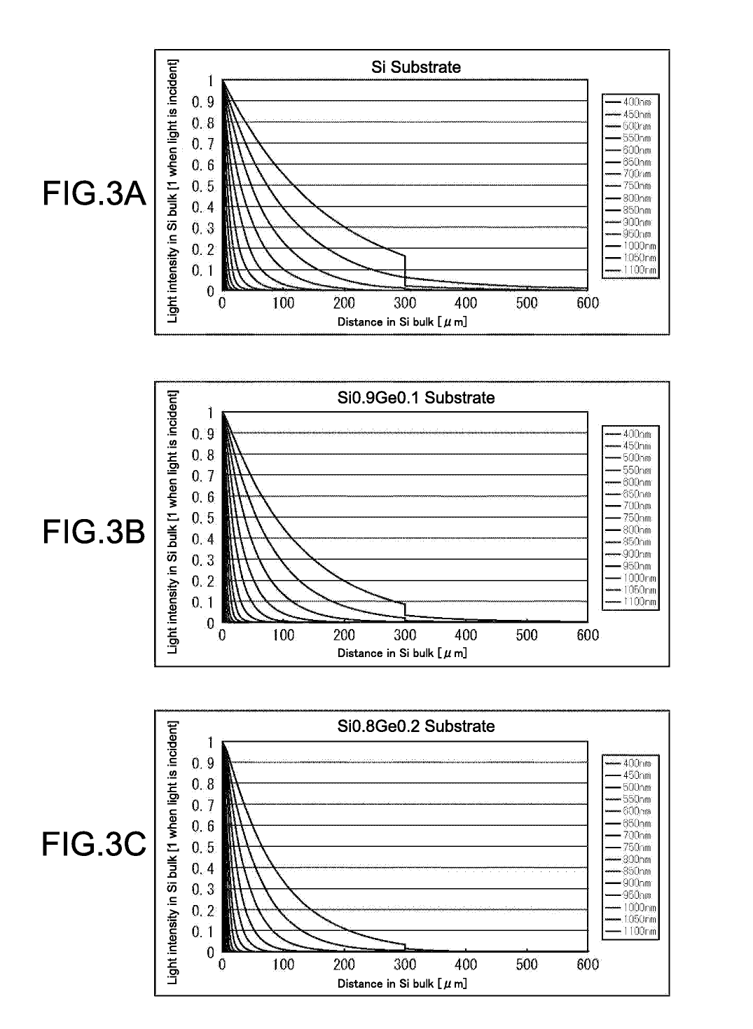

FIG. 3A shows an example of a simulation result of a light intensity change depending on a distance in the incident light travelling in the silicon (Si) single crystal substrate within a wavelength between 400 nm to 1100 nm.

FIG. 3B shows an example of a simulation result of a light intensity change depending on a distance in the incident light travelling in the silicon-germanium (SiGe) mixed crystal substrate 121 containing 10% of germanium (Ge) within a wavelength between 400 nm to 1100 nm.

FIG. 3C shows an example of a simulation result of a light intensity change depending on a distance in the incident light travelling in the silicon-germanium (SiGe) mixed crystal substrate 121 containing 20% of germanium (Ge) within a wavelength between 400 nm to 1100 nm.

In each case, the longer the wavelength is, the lower the percentage of the decrease in the light intensity is. In other words, the attenuation rate at the wavelength of 1100 nm is the lowest.

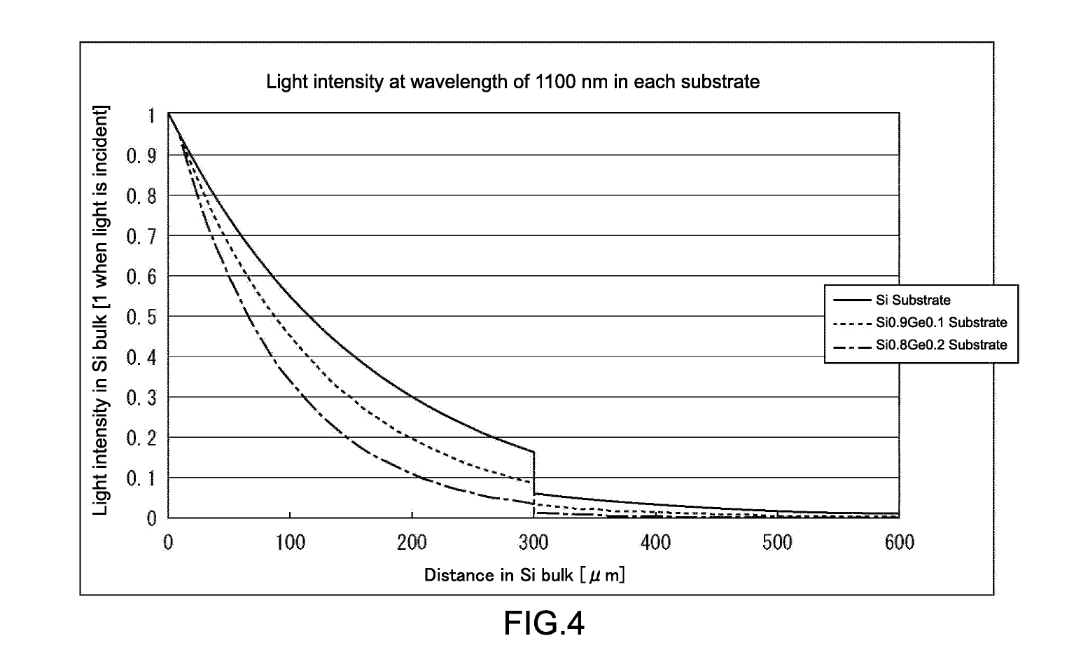

The attenuation rates at the wavelength of 1100 nm in the respective substrates are compared. FIG. 4 is a graph showing an example of a simulation result.

In the graph shown FIG. 4, a solid line represents the light intensity at the wavelength of 1100 nm of the silicon (Si) single crystal substrate, a dotted line represents the light intensity at the wavelength of 1100 nm of the silicon-germanium (SiGe) mixed crystal substrate 121 containing 10% of germanium (Ge), and a dashed line represents the light intensity at the wavelength of 1100 nm of the silicon-germanium (SiGe) mixed crystal substrate 121 containing 20% of germanium (Ge).

The device substrate (in the CMOS image sensor 100, the silicon epitaxial layer 123 and the silicon-germanium (SiGe) mixed crystal substrate 121) has a film thickness of 300 μm. A reflectance at a rear surface of the silicon-germanium (SiGe) mixed crystal substrate 121 is 38% (=(4.2−1)̂2/(4.2+1)̂2=(refractive index of Si−refractive index of air)̂2/(refractive index of Si+refractive index of air)̂2).

In this case, at near 600 μm of the abscissa axis in the graph shown in FIG. 4, it represents the percentage of the incident light reflected at the rear surface of the device (the rear surface of the silicon-germanium (SiGe) mixed crystal substrate 121) and arrived at the photodiode region (the photodiode 124) at a light receiving side. Specifically, about 1% of the light having the wavelength of 1100 nm is reflected at the rear surface of the silicon-germanium (SiGe) mixed crystal substrate 121 and arrived at the photodiode 124. The percentage is based on the light incident on the CMOS image sensor 100 defining as 100%.

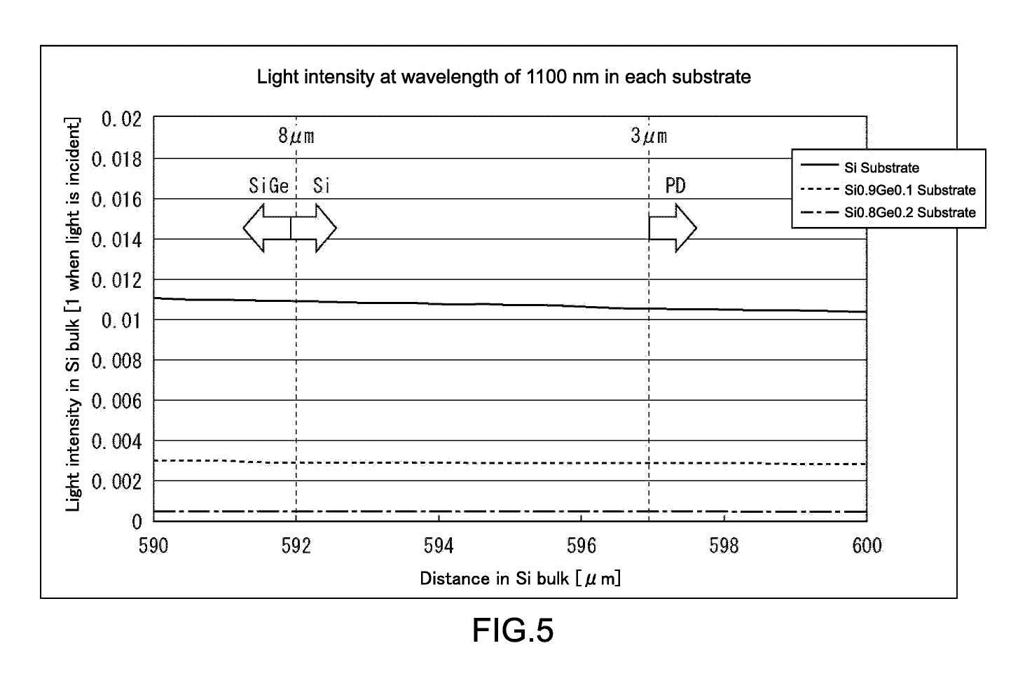

FIG. 5 is a graph provided by enlarging the abscissa axis at near 600 μm in the graph.

When the thickness of the photodiode 124 is 3 μm, the range from 597 μm to 600 μm of the abscissa axis in the graph corresponds to the thickness of the photodiode 124.

In the simulation result, in the silicon (Si) single crystal substrate, the percentage of the incident light having the wavelength of 1100 nm reflected at the rear surface of the device and absorbed at the photodiode 124 is 0.0186% based on the light incident on the device defining as 100%, in the silicon-germanium (SiGe) mixed crystal substrate 121 containing 10% of germanium (Ge), the percentage of the incident light having the wavelength of 1100 nm reflected at the rear surface of the device and absorbed at the photodiode 124 is 0.0051% (about one-fourth of the silicon (Si) single crystal substrate) based on the light incident on the device defining as 100%, in the silicon-germanium (SiGe) mixed crystal substrate 121 containing 20% of germanium (Ge), the percentage of the incident light having the wavelength of 1100 nm reflected at the rear surface of the device and absorbed at the photodiode 124 is 0.0009% (about one-twentieth of the silicon (Si) single crystal substrate) based on the light incident on the device defining as 100%.

The attenuation of the photodiode 124 (in the range from 597 μm to 600 μm of the abscissa axis in the graph) corresponds to the light intensity obtained by the photoelectric conversion. In other words, the attenuation will contribute to aliasing.

As shown in the simulation result mentioned above, by increasing the germanium concentration, the attenuation can be decreased. Thus, the occurrences of the color mixing and the black shift can be inhibited.

According to the embodiment of the present disclosure, the image sensor uses the substrate formed of a material having a light absorption coefficient higher than that of silicon in place of the silicon single crystal substrate. As long as the material has a light absorption coefficient higher than that of silicon, any material can be used. In other words, the material is not limited to the above-mentioned silicon-germanium (SiGe) mixed crystal.

For example, a compound of silicon and gallium antimonide GsSb having a band gap of 0.7 [eV], indium nitride InN having a band gap of 0.7 [eV], indium arsenide InAs having a band gap of 0.36 [eV], lead sulfide PbS having a band gap of 0.37 [eV], lead selenide PbSe having a band gap of 0.27 [eV] or lead telluride PbTe having a band gap of 0.29 [eV] (all at a temperature of 302 [K]), each of which is a band gap lower than that, i.e., 1.11 [eV], of silicon (Si), may be used in the substrate.

Among them, germanium (Ge) is composed of a single element, can easily provide large single crystal as compared with the other materials as described above, and is less distorted when it is combined with silicon (Si) crystal. A possibility of combining silicon with germanium is higher than other materials, which means germanium can be easily combined with silicon.

The germanium concentration (Ge) in the silicon-germanium (SiGe) mixed crystal substrate 121 shown in FIG. 2 may not be even (uniform), and may change (non-uniform) depending on the position. For example, the germanium (Ge) concentration may change in a depth direction (a perpendicular direction in FIG. 2).

As an example, the germanium (Ge) concentration may be higher at a deeper position (below the center in FIG. 2) as seen from the light incident side of the silicon-germanium (SiGe) mixed crystal substrate 121. That is to say, the germanium (Ge) concentration may be lower at a shallower position (above the center in FIG. 2) as seen from the light incident side. With such a configuration, the germanium (Ge) concentration at around the interface between the silicon-germanium (SiGe) mixed crystal substrate 121 and the silicon epitaxial layer 123 can be lowered, an epitaxial growth may be successfully achieved. Since the silicon epitaxial layer 123 can be easily produced, the yield can be increased and the production costs can be decreased.

### 2. Second Embodiment

### [Production Apparatus]

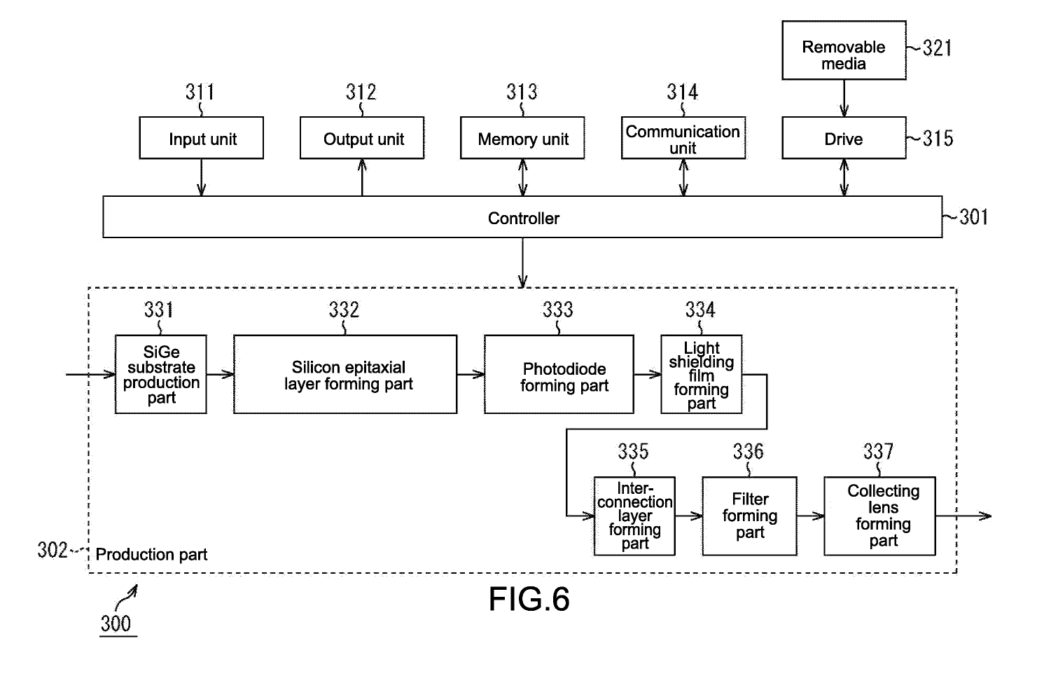

FIG. 6 is a block diagram showing a major configuration example of a production apparatus for producing an image sensor according to the embodiment of the present disclosure. The production apparatus 300 shown in FIG. 6 is, for example, for producing the CMOS image sensor 100 shown in FIG. 2 as the image sensor according to the embodiment of the present disclosure. The production apparatus 300 produces the image sensor including the substrate formed of the material having the light absorption coefficient higher than that of silicon.

The production apparatus 300 includes a controller 301 and a production part 302.

The controller 301 includes a CPU (Central Processing Unit), a ROM (Read Only Memory), a RAM (Random Access Memory) and the like, and controls each part of the production part 302 to perform a control processing of the production of the CMOS image sensor 100. For example, the CPU in the controller 301 performs various processes in accordance with the program stored in the ROM. The CPU performs various processes in accordance with the program loaded from a memory unit 313 to the RAM. Data necessary for performing various processes by the CPU and the like is stored to the RAM, as appropriate.

The production apparatus 300 includes an input unit 311, an output unit 312, the memory unit 313, a communication unit 314 and a drive 315.

The input unit 311 may have a keyboard, a mouse, a touch panel, an external input terminal or the like, which receives a user's indication and external information input and provide them to the controller 301. The output unit 312 may have a display such as a CRT (Cathode Ray Tube) display and an LCD (Liquid Crystal Display) display, a speaker, an external output terminal or the like, which outputs a wide variety of information provided from the controller 301 as an image, a sound, an analog signal or digital data.

The memory unit 313 may have an SSD (Solid State Drive) such as flash memory, a hard disc or the like, which may store the information provided by the controller 301, read-out and provide the stored information, and the like.

The communication unit 314 may have an interface, a modem or the like including, for example, a wired LAN (Local Area Network) or a wireless LAN, which communicates with an external apparatus via a network including an internet. For example, the communication unit 314 sends the information provided by the controller 301 to a communication partner, and provides the controller 301 with the information received from the communication partner.

The drive 315 is connected to the controller 301, as appropriate. A removable media 321 such as a magnetic disc, an optical disc, a magnetic optical disc and a semiconductor memory is mounted onto the drive 315, as appropriate. A computer program read-out from the removable media 321 via the drive 315 is installed on the memory unit 313, as appropriate.

The production part 302 is controlled by the controller 301 to perform the process with regard to the production of the image sensor (CMOS image sensor) according to the embodiment of the present disclosure. The production part 302 includes a silicon-germanium (SiGe) substrate production part 331, a silicon epitaxial layer forming part 332, a photodiode forming part 333, a light shielding film forming part 334, an interconnection layer forming part 335, a filter forming part 336 and a collecting lens forming part 337.

In the silicon-germanium (SiGe) substrate production part 331, the silicon-germanium mixed crystal substrate 121 is produced while the production is controlled by the controller 301. More specifically, in the process by the silicon-germanium (SiGe) substrate production part 331, a silicon-germanium wafer to be provided may be set as the silicon-germanium mixed crystal substrate 121, or it may be started from a process that a silicon-germanium ingot is sliced to form a wafer, or it may be started from a process that germanium is added and combined to/with germanium to form an ingot. The silicon-germanium (SiGe) substrate production part 331 provides the silicon epitaxial layer forming part 332 with the silicon-germanium mixed crystal substrate 121 produced.

In the silicon epitaxial layer forming part 332, silicon is epitaxially grown on the provided silicon-germanium mixed crystal substrate 121 to form a silicon epitaxial layer 123 while the formation is controlled by the controller 301. The silicon epitaxial layer forming part 332 provides the photodiode forming part 333 with a device including the silicon-germanium mixed crystal substrate 121 on which the silicon epitaxial layer 123 is laminated.

In the photodiode forming part 333, photodiodes 124 are formed on the silicon epitaxial layer 123 of the provided device while the formation is controlled by the controller 301. The photodiode forming part 333 provides the light shielding film forming part 334 with the device on which the photodiodes 124 are formed.

In the light shielding film forming part 334, an insulation film 126, in which a light shielding film 125 is formed, is formed on the silicon epitaxial layer 123, in which the photodiodes 124 of the pixels are formed, at the OB region (OB 111) of the provided device, while the formation is controlled by the controller 301. The light shielding film forming part 334 provides the interconnection layer forming part 335 with the device on which the insulation film 126 is laminated.

In the interconnection layer forming part 335, the interconnection layer 127 including the interconnections 128 are formed on the insulation film 126 of the provided device, while the formation is controlled by the controller 301. The interconnection layer forming part 335 provides the filter forming part 336 with the device on which the interconnection layer 127 is laminated.

In the filter forming part 336, a color filter 129 is formed on the interconnection layer 127 of the provided device on a pixel to pixel basis, while the formation is controlled by the controller 301. The filter forming part 336 provides the collecting lens forming part 337 with the device on which the color filter 129 is laminated.

In the collecting lens forming part 337, the collecting lens 130 that collects the incident light on the photodiode 124 is formed on the color filter 129 of the provided device on a pixel to pixel basis, while the formation is controlled by the controller 301.

As described above, the CMOS image sensor 100 is produced.

The collecting lens forming part 337 puts out the produced CMOS image sensor 100 outside the production apparatus 300. The CMOS image sensor 100 put out may be subjected to various tests at the time of production or be packaged.

Thus, the production apparatus 300 can produce the CMOS image sensor 100 capable of inhibiting the occurrences of the color mixing and the black shift by using the silicon-germanium mixed crystal substrate 121 having a light absorption coefficient higher than that of silicon in place of the silicon single crystal substrate.

In addition, as the silicon epitaxial layer forming part 332 forms a silicon single crystal epitaxial layer on the silicon-germanium mixed crystal substrate 121, the production apparatus 300 can produce more easily the CMOS image sensor 100 in a similar method as the image sensor in the related art using the silicon single crystal substrate.

### [Flow of Production Process]

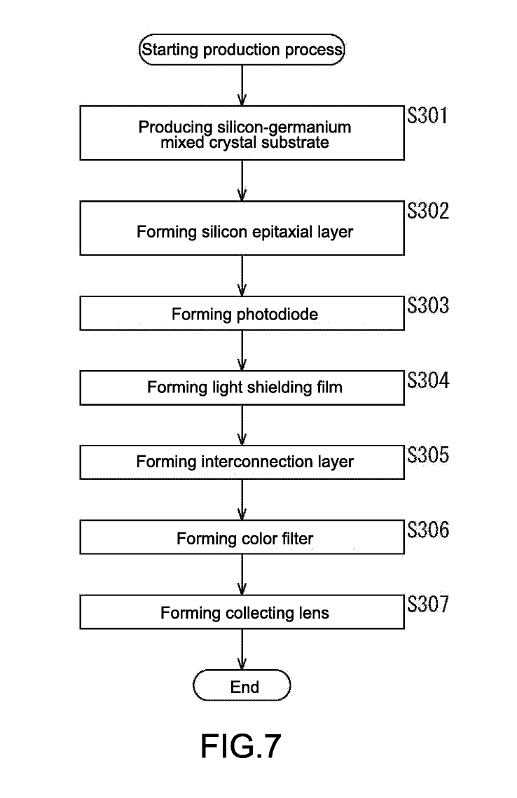

FIG. 7 is a flow chart illustrating an example of a flow of a production process.

Once the production process is started, the silicon-germanium (SiGe) substrate production part 331 produces the silicon-germanium mixed crystal substrate 121 while the production is controlled by the controller 301 in a step S301.

In a step S302, the silicon epitaxial layer forming part 332 epitaxially grows silicon on the silicon-germanium mixed crystal substrate 121 and forms a silicon epitaxial layer 123 while the formation is controlled by the controller 301.

In a step S303, the photodiode forming part 333 forms photodiodes 124 on the silicon epitaxial layer 123 while the formation is controlled by the controller 301.

In a step S304, the light shielding film forming part 334 forms an insulation film 126, in which a light shielding film 125 is formed in the pixel at the OB region (OB 111), is formed on the silicon epitaxial layer 123, in which the photodiodes 124 are formed, while the formation is controlled by the controller 301.

In a step S305, the interconnection layer forming part 335 forms the interconnection layer 127 including the interconnections 128 on the insulation film 126, while the formation is controlled by the controller 301.

In a step S306, the filter forming part 336 forms a color filter 129 on the interconnection layer 127 on a pixel to pixel basis, while the formation is controlled by the controller 301.

In a step S307, the collecting lens forming part 337 forms the collecting lens 130 that collects the incident light on the photodiode 124 on the color filter 129 on a pixel to pixel basis, while the formation is controlled by the controller 301.

As described above, after the CMOS image sensor 100 is produced, the production part 302 ends the production process.

By performing the respective processes as described above, the production apparatus 300 can produce the CMOS image sensor 100 according to the embodiment of the present disclosure capable of inhibiting the occurrences of the color mixing and the black shift.

The embodiment of the present disclosure can be applied not only to the image sensor, but also to any apparatus including the image sensor as described above.

### 3. Third Embodiment

### [Imaging Apparatus]

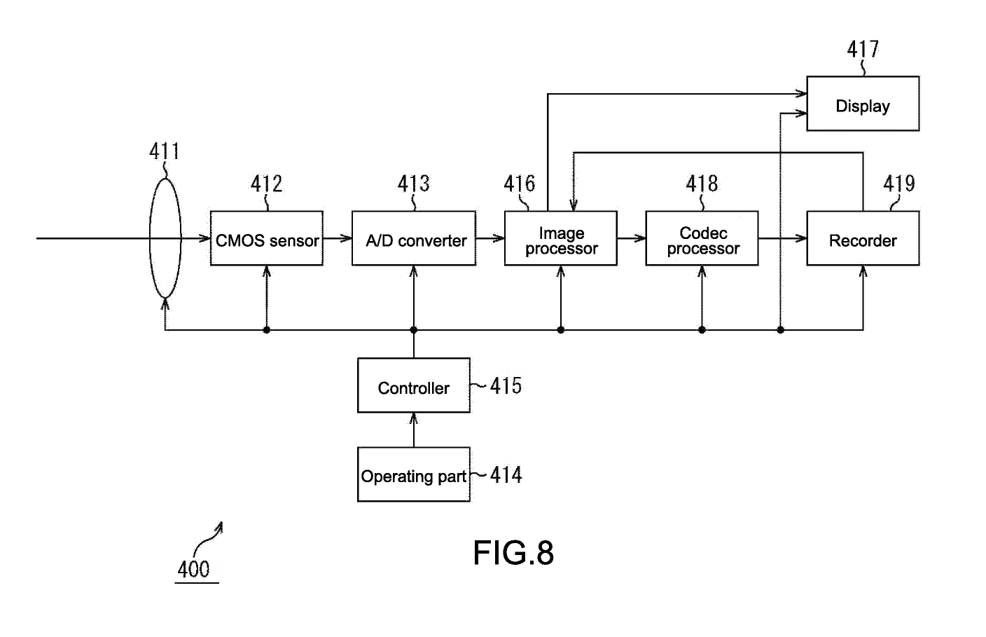

FIG. 8 is a block diagram showing a major configuration example of an imaging apparatus according to an embodiment of the present disclosure. An imaging apparatus 400 shown in FIG. 8 is an apparatus for imaging an object and outputting an image of the object as an electric signal.

As shown in FIG. 8, the imaging apparatus 400 includes a lens 411, a CMOS sensor 412, an A/D converter 413, an operating part 414, a controller 415, an image processor 416, a display 417, a codec processor 418, and a recorder 419.

The lens 411 adjusts a focus to the object, collects light in focus, and provides the CMOS sensor 412 with the light.

The CMOS sensor 412 photoelectrically converts the light from the object incident via the lens 411, and provides the A/D converter 413 with the light as an electrical signal.

The A/D converter 413 converts the electric signal on a pixel to pixel basis fed by the CMOS sensor 412 at a predetermined timing to a digital image signal (hereinafter referred to as a pixel signal or an image data), and feeds it sequentially to the image processor 416 at a predetermined timing.

The operating part 414 is composed, for example, of Jog Dial™, a key, a button, a touch panel or the like. When a user manipulates the apparatus and inputs a signal, the operating part 414 feeds the signal to the controller 415.

Based on the signal the user inputs at the operating part 414, the controller 415 controls the operation of the lens 411, the CMOS sensor 412, the A/D converter 413, the image processor 416, the display 417, the code processor 418 and the recorder 419, and makes them take an image.

The image processor 416 manipulates and processes the image signal fed from the A/D converter 413 including the above-mentioned black level correction, color mixing correction, defect correction, de-mosaic processing, matrix processing, gamma correction, YC conversion and the like. The image processor 416 feeds the image signal manipulated to the display 417 and the codec processor 418.

The display 417 is composed, for example, of a liquid crystal display, and displays the image of the object based on the image signal from the image processor 416.

The codec processor 418 encodes the image signal from the image processor 416 in the predetermined manner, and feeds an image data provided by encoding, to the recorder 419.

The recorder 419 records the image data from the codec processor 418. The image data recorded on the recorder 419 is read-out by the image processor 416, as appropriate, and is fed to the display 417 to display a corresponding image.

As the CMOS sensor 412 of the imaging apparatus 400, the image sensor (for example, the CMOS image sensor 100 shown in FIG. 2) including the substrate formed of the material having the light absorption coefficient higher than that of silicon as described in the first Embodiment is used so that the imaging apparatus 400 can inhibit the occurrences of the color mixing and the black shift.

The image sensor according to the embodiment of the preset disclosure can be applied not only to the image apparatus having the configuration described above, but also to any information processing apparatus having an imaging function such as a digital still camera, a video camera, a mobile phone, a smartphone, a tablet type device, a personal computer and the like. Also, it can be applied to a camera module mounted on other information processing apparatuses (or mounted on embedded devices).

For example, a night vision camera utilizes near-infrared light in order to take an image in the dark. Accordingly, the night vision camera might not use an IR cut filter for blocking the near-infrared light. As the image sensor of such a night vision camera, the image sensor including the silicon single crystal substrate has been applied in the past.

However, in this case, when the night vision camera is irradiated with near-infrared light having a wavelength of about 1100 nm, the pixel value at the OB region may become peculiar as described above, and the image may be crashed. That is to say, when an intruder irradiates the night vision camera with the near-infrared light, the image may be crashed and the night vision camera may be useless. Moreover, since the near-infrared is in a wavelength range outside the visible light, the action in which the night vision camera is irradiated with the near-infrared light is hard to be found by a third party.

In contrast, when the image sensor according to the embodiment of the present disclosure is applied to the night vision camera, the occurrences of the color mixing and the black shift can be more inhibited. In other words, even when the night vision camera is irradiated with the near-infrared light, the image taken by the night vision camera can be prevented from crashing.

A series of the processing as described above can be carried out by a hardware, and also by a software. When the series of the processing as described above is carried out by the software, a program constituting the software is installed via a network or a recording medium.

The recording medium may be configured by a removable media 321, on which a program is recorded for distributing it to a user, separated from the apparatus, as shown in FIG. 6, for example. The removable media 321 includes a magnetic disc (including a flexible disc), an optical disc (including a CD-ROM and a DVD), a magnetic optical disc (including MD (Mini Disc)), a semiconductor memory or the like. In addition to the removable media 321, the above-mentioned recording medium may be configured by a ROM in which a program is recorded to be distributed to a user in a state that it is embedded in the apparatus in advance, and a hard disk included in the memory 313.

The program executed by the computer may be a program processed in chronological order as described herein, or a program processed in parallel or in a timing as necessary such as when invoking.

Also herein, the step of describing the program recorded in the recording medium may include the process conducted in chronological order in accordance with the described order, and the process conducted not necessarily in chronological order but in parallel or individually.

The system herein means the whole apparatus configured by a plurality of devices (apparatuses).

One apparatus (or one process part) described above may be divided into a plurality of apparatuses (or a plurality of process parts). In an opposite manner, a plurality of apparatuses (or a plurality of process parts) may be brought together as one. It should be appreciated that components other than those described above may be added to each apparatus (or each process part). As long as the configuration or behavior of the system as a whole is substantially the same, a part of the apparatus (or the process part) may be involved in other apparatus (or other process part). In fact, the present disclosure is not limited to the above-described embodiments, and various modifications can be made without departing from the spirit of the present disclosure.

The present disclosure may have the following configurations.

(1) An image sensor, including:

a substrate formed of a material having a light absorption coefficient higher than that of silicon, and

a photoelectric conversion element formed on the substrate for photoelectrically converting incident light.

(2) The image sensor according to (1) above, in which

the substrate is formed of a material having a light absorption coefficient of light having a wavelength longer than light in a visual light region.

(3) The image sensor according to (2) above, in which

the substrate is formed of a material having a high light absorption coefficient of near-infrared light.

(4) The image sensor according to (3) above, in which

the substrate is formed of silicon-germanium.

(5) The image sensor according to any one of (1) to (4) above, further including

a silicon epitaxial layer provided by epitaxially grown silicon on the substrate, in which

the photoelectric conversion element is formed on the silicon epitaxial layer.

(6) The image sensor according to (5) above, in which

the substrate is formed of silicon-germanium having an uneven germanium concentration.

(7) The image sensor according to (6) above, in which

the germanium concentration of the substrate is made lower towards a position shallower as seen from a light incident side.

(8) The image sensor according to any one of (1) to (7) above, further including

an insulation film formed on the photoelectric conversion element.

(9) The image sensor according to (8) above, further including

a light shielding film for shielding external light formed on the photoelectric conversion element in a pixel at an optical black region.

(10) The image sensor according to (8) or (9) above, further including

an interconnection layer formed on the insulation film.

(11) The image sensor according to (10) above, further including

a color filter formed on the interconnection layer on a pixel to pixel basis, and

a collecting lens formed on the color filter on a pixel to pixel basis.

(12) A production apparatus of producing an image sensor, including:

a substrate production part for producing a substrate formed of a material having a light absorption coefficient higher than that of silicon, and

a photoelectric conversion element production part for forming a photoelectric conversion element, which photoelectrically converts incident light, on the substrate produced at the substrate production part.

(13) The image sensor according to (12) above, further including

a silicon epitaxial layer production part for epitaxially growing silicon on the substrate produced at the substrate production part to form a silicon epitaxial layer thereon.

(14) A method of producing a production apparatus of producing an image sensor, including:

producing a substrate formed of a material having a light absorption coefficient higher than that of silicon at a substrate production part, and

forming a photoelectric conversion element, which photoelectrically converts incident light, on the substrate produced at the substrate production part at a photoelectric conversion element production part.

(15) An imaging apparatus, including:

an image sensor for imaging an object and outputting an image of the object as an electric signal, and

an image processor for image-processing the object obtained by the image sensor, in which

the image sensor includes
a substrate formed of a material having a light absorption coefficient higher than that of silicon, and
a photoelectric conversion element formed on the substrate for photoelectrically converting incident light.

(16) The imaging apparatus according to (15) above, in which

the substrate is formed of a material having a light absorption coefficient of light having a wavelength longer than light in a visual light region.

(17) The imaging apparatus according to (16) above, in which

the substrate is formed of silicon-germanium.

(18) The imaging apparatus according to any one of (15) to (17) above, further including

a silicon epitaxial layer provided by epitaxially grown silicon on the substrate, in which

the photoelectric conversion element is formed on the silicon epitaxial layer.

(19) The imaging apparatus according to (18) above, in which

the substrate is formed of silicon-germanium having an uneven germanium concentration.

(20) The imaging apparatus according to (19) above, in which

the germanium concentration of the substrate is made lower towards a position shallower as seen from a light incident side.

The present disclosure contains subject matter related to that disclosed in Japanese Priority Patent Application JP 2012-014858 filed in the Japan Patent Office on Jan. 27, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An image sensor, comprising:
a substrate formed of a material having a light absorption coefficient higher than that of silicon, and
a photoelectric conversion element formed on the substrate for photoelectrically converting incident light.

2. The image sensor according to according to claim 1, wherein
the substrate is formed of a material having a light absorption coefficient of light having a wavelength longer than light in a visual light region.

3. The image sensor according to claim 2, wherein
the substrate is formed of a material having a high light absorption coefficient of near-infrared light.

4. The image sensor according to claim 3, wherein
the substrate is formed of silicon-germanium.

5. The image sensor according to claim 1, further including
a silicon epitaxial layer provided by epitaxially grown silicon on the substrate, wherein
the photoelectric conversion element is formed on the silicon epitaxial layer.

6. The image sensor according to claim 5, wherein
the substrate is formed of silicon-germanium having an uneven germanium concentration.

7. The image sensor according to claim 6, wherein
the germanium concentration of the substrate is made lower towards a position shallower as seen from a light incident side.

8. The image sensor according to claim 1, further including
an insulation film formed on the photoelectric conversion element.

9. The image sensor according to claim 8, further including
a light shielding film for shielding external light formed on the photoelectric conversion element in a pixel at an optical black region.

10. The image sensor according to claim 8, further including
an interconnection layer formed on the insulation film.

11. The image sensor according to claim 10, further including
a color filter formed on the interconnection layer on a pixel to pixel basis, and
a collecting lens formed on the color filter on a pixel to pixel basis.

12. A production apparatus of producing an image sensor, including:
a substrate production part for producing a substrate formed of a material having a light absorption coefficient higher than that of silicon, and
a photoelectric conversion element production part for forming a photoelectric conversion element, which photoelectrically converts incident light, on the substrate produced at the substrate production part.

13. The image sensor according to claim 12, further including
a silicon epitaxial layer production part for epitaxially growing silicon on the substrate produced at the substrate production part to form a silicon epitaxial layer thereon.

14. A method of producing a production apparatus of producing an image sensor, comprising:
producing a substrate formed of a material having a light absorption coefficient higher than that of silicon at a substrate production part, and
forming a photoelectric conversion element, which photoelectrically converts incident light, on the substrate produced at the substrate production part at a photoelectric conversion element production part.

15. An imaging apparatus, comprising:
an image sensor for imaging an object and outputting an image of the object as an electric signal, and
an image processor for image-processing the object obtained by the image sensor, wherein
the image sensor includes
a substrate formed of a material having a light absorption coefficient higher than that of silicon, and
a photoelectric conversion element formed on the substrate for photoelectrically converting incident light.

16. The imaging apparatus according to claim 15, wherein
the substrate is formed of a material having a light absorption coefficient of light having a wavelength longer than light in a visual light region.

17. The imaging apparatus according to claim 16, wherein
the substrate is formed of silicon-germanium.

18. The imaging apparatus according to claim 15, further including
a silicon epitaxial layer provided by epitaxially grown silicon on the substrate, wherein
the photoelectric conversion element is formed on the silicon epitaxial layer.

19. The imaging apparatus according to claim 18, wherein
the substrate is formed of silicon-germanium having an uneven germanium concentration.

20. The imaging apparatus according to claim 19, wherein
the germanium concentration of the substrate is made lower towards a position shallower as seen from a light incident side.
